(19) United States
(12) Patent Application Publication
(10) Pub. No.: US 2026/0341385 A1
(43) Pub. Date: Oct. 29, 2026

(54) FLASH MEMORY DEVICE AND TESTING METHOD THEREOF

(71) Applicant: Winbond Electronics Corp., Taichung City (TW)

(72) Inventors: Hong-Lin Yue, Taichung City (TW); Chien-Min Wu, Taichung City (TW); Shao-Ching Liao, Taichung City (TW)

(73) Assignee: Winbond Electronics Corp., Taichung City (TW)

(21) Appl. No.: 19/547,614

(22) Filed: Feb. 23, 2026

(30) Foreign Application Priority Data
Apr. 24, 2025 (TW) 114115461

(51) Int. Cl. G11C 29/12

(52) U.S. Cl. CPC G11C 29/12005; G11C 29/1201

(57) ABSTRACT

A flash memory device and a testing method thereof are provided. The testing method includes following steps: performing an erase operation on a mini array, a test memory cell and a main array; measuring a relationship between a drain current and a gate voltage for each of the mini array, test memory cell and the main array, to record a first current-voltage curve, a second current-voltage curve and a third current-voltage curve respectively corresponding to the main array, the test memory cell and the mini array; analyzing the second current-voltage curve and the third current-voltage curve to obtain a target middle voltage point; analyzing the first current-voltage curve to obtain a left range length; analyzing the third current-voltage curve to obtain a right range length; and drawing a threshold voltage distribution according to the target middle voltage point, the left range length and the right range length.

### CROSS-REFERENCE TO RELATED APPLICATION

This application claims the priority benefit of Taiwan application serial no. 114115461, filed on April 24, 2025. The entirety of the above-mentioned patent application is hereby incorporated by reference herein and made a part of this specification.

### BACKGROUND

### TECHNICAL FIELD

The present invention relates to a memory test technology, and particularly relates to a flash memory device and the testing method employed thereby.

### RELATED ART

For a flash memory, a threshold voltage distribution is one of the important considerations for memory cell performance and reliability. Since during the programming and erasing operations of memory cells, the threshold voltage distribution after an erasing operation of the memory chip will affect the overall operation of the chip, it is very important to use a testing method to accurately obtain the threshold voltage distribution. However, the current method for generating the threshold voltage distribution still requires testing each memory cell (bit), which requires a considerable amount of test time and does not meet economic efficiency.

### SUMMARY

The present invention provides a flash memory device and a testing method thereof, which may effectively reduce the test time.

The flash memory device of the present invention includes a memory chip and a memory control circuit. The memory chip has a mini array, test memory cells and a main array. The memory control circuit is coupled to the memory chip. The memory control circuit performs erasing operation on the mini array, test memory cells and main array, and then measures a relationship between a drain current and a gate voltage for each of the mini array, test memory cells and main array, to record a first current-voltage curve, a second current-voltage curve and a third current-voltage curve respectively corresponding to the main array, test memory cells and mini array. The memory control circuit analyzes the second current-voltage curve and the third current-voltage curve to obtain a target middle voltage point. The memory control circuit analyzes the first current-voltage curve to obtain a left range length. The memory control circuit analyzes the third current-voltage curve to obtain a right range length. The memory control circuit draws a threshold voltage distribution according to the target middle voltage point, the left range length and the right range length.

The testing method of the flash memory device of the present invention includes the following steps: performing an erasing operation on the mini array, the test memory cell and the main array; measuring a relationship between a drain current and a gate voltage for each of the mini array, the test memory cell and the main array, to record a first current-voltage curve, a second current-voltage curve and a third current-voltage curve respectively corresponding to the main array, the test memory cell and the mini array; analyzing the second current-voltage curve and the third current-voltage curve to obtain a target middle voltage point; analyzing the first current-voltage curve to obtain a left range length; analyzing the third current-voltage curve to obtain a right range length; and drawing a threshold voltage distribution according to the target middle voltage point, the left range length and the right range length.

Based on the above, the flash memory device and the testing method thereof of the present invention do not need to test each memory cell (bit), and may quickly evaluate the threshold voltage distribution of the chip, effectively reducing the test time required to generate the threshold voltage distribution. As such, it is beneficial for improving product development, yield verification, chip probing (CP) and other procedures, enhancing the efficiency of chip calibration.

To make the above features and advantages of this case more apparent and understandable, embodiments are specifically provided below, with detailed explanations in conjunction with the accompanying drawings.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 illustrates a block diagram of a flash memory device according to an embodiment of the present invention.

FIG. 2, FIG. 4 to FIG. 6 illustrate step flowcharts of a testing method of a flash memory device according to an embodiment of the present invention.

FIG. 3 illustrates an example of a current-voltage curve according to an embodiment of the present invention.

FIG. 7 illustrates an example of a threshold voltage distribution according to an embodiment of the present invention.

### DESCRIPTION OF THE EMBODIMENTS

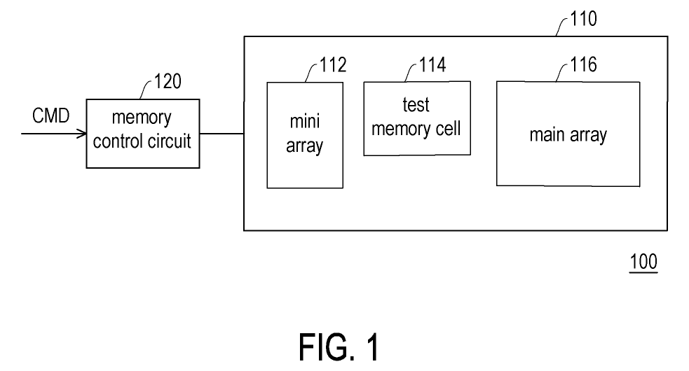

Please refer to FIG. 1, the flash memory device 100 includes a memory chip 110 and a memory control circuit 120. The memory chip 110 has a mini array 112, a test memory cell 114, and a main array 116. The mini array 112, test memory cell 114, and main array 116 are, for example, constituted by NOR-type flash memory components (memory cells). In this embodiment, the mini array 112 is a memory array independent from the main array 116. The test memory cell 114 is a memory cell operating individually in another smaller array (e.g., 4 bits). The mini array 112 and the test memory cell 114 may be placed on the same memory structure, while the main array 116 may be placed on another memory structure. The size of the mini array 112 is, for example, 1k bits, and the size of the main array 116 is, for example, 512k bits, but the present invention is not limited to this.

The memory control circuit 120 is coupled to the memory chip 110. The memory control circuit 120 may test the memory chip 110 according to a received command CMD. The memory control circuit 120, besides being, for example, a state machine, a central processing unit, or other programmable general-purpose or special-purpose microprocessors, digital signal processors, programmable controllers, application-specific integrated circuits, programmable logic devices, or other similar devices or combinations of these devices, may also be a hardware circuit designed through hardware description language or any other known digital circuit design method, and implemented through field-programmable gate arrays or complex programmable logic devices or other methods.

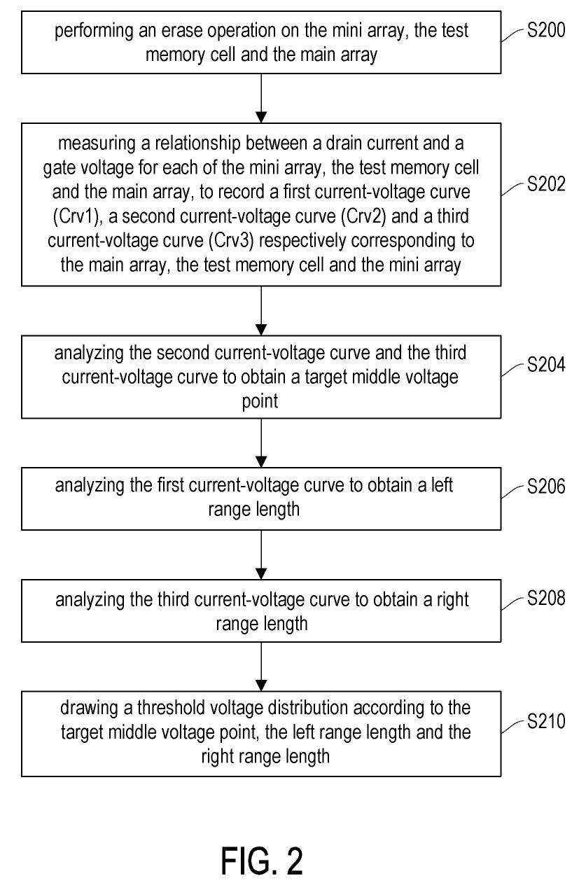

Please refer to both FIG. 1 and FIG. 2, the testing method of the flash memory device in this embodiment is applicable to the flash memory device 100 in FIG. 1. The following explains each step of the testing method of the embodiment of the present invention in conjunction with the various components in the flash memory device 100.

First, in step S200, the memory control circuit 120 performs an erase operation on the mini array 112, the test memory cell 114, and the main array 116. For example, the memory control circuit 120 may apply an erase voltage to the well regions corresponding to the mini array 112, the test memory cell 114, and the main array 116 to perform a large-scale erasure with a block as a unit, and complete the erase operation after passing an erase verification.

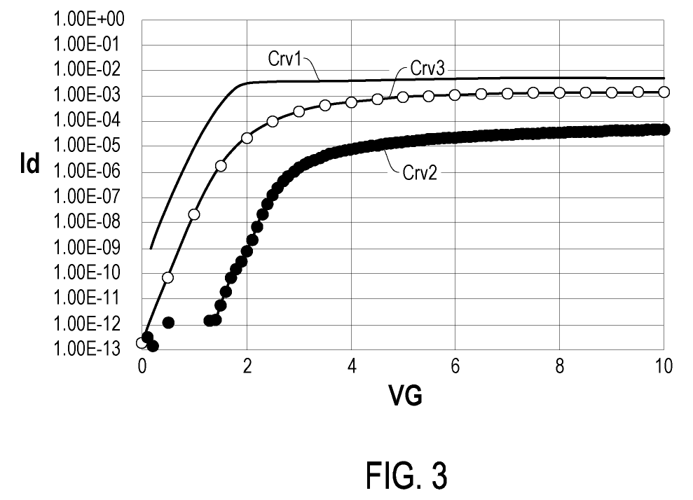

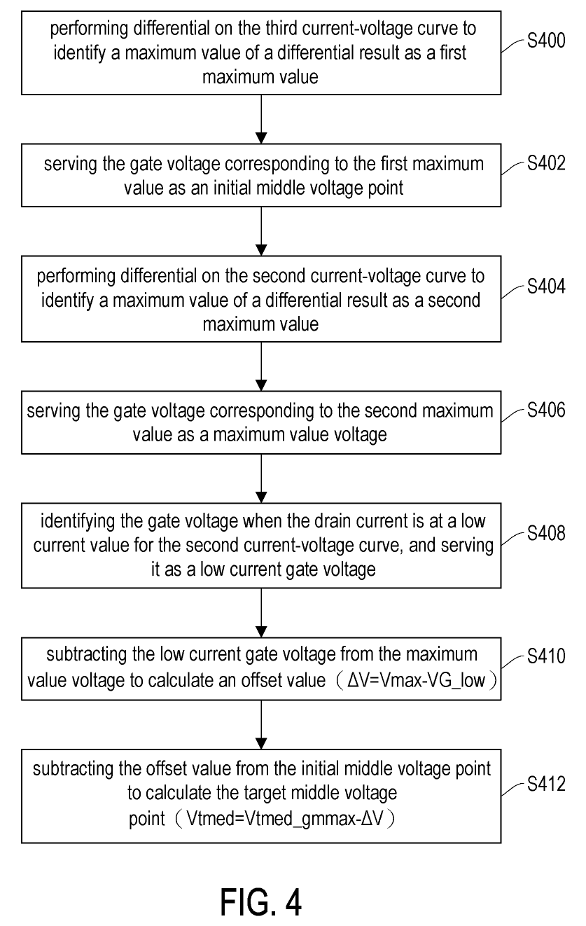

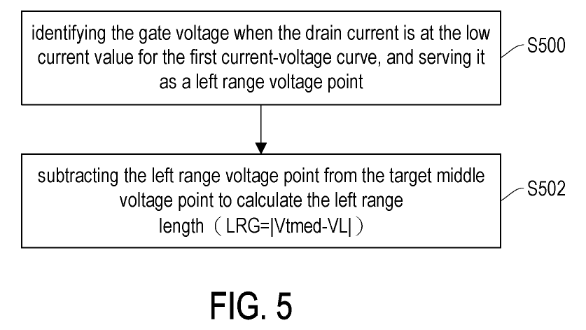

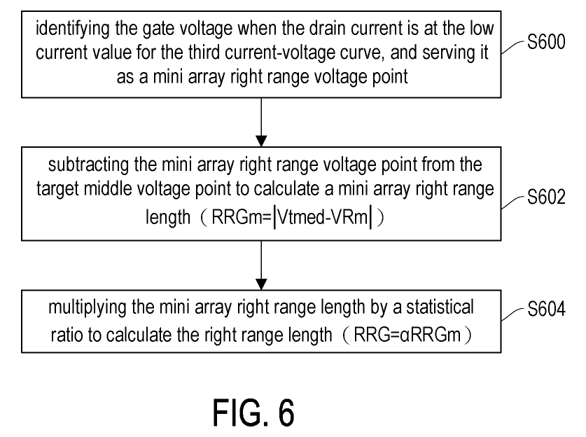

Following, in step S202, the memory control circuit 120 measures a relationship between a drain current Id and a gate voltage VG for each of the mini array 112, the test memory cell 114, and the main array 116, to record the first current-voltage curve Crv1, the second current-voltage curve Crv2, and the third current-voltage curve Crv3 corresponding to the main array 116, the test memory cell 114, and the mini array 112, respectively. In this embodiment, the gate voltage VG refers to the voltage applied through the word line to the gates of the test memory cell 114 and each memory cell in the mini array 112 and the main array 116, and the drain current Id refers to the sum of the currents flowing from the source to the drain of the test memory cell 114 and each memory cell in the mini array 112 and the main array 116 in response to the gate voltage VG applied to the gate. These measured relationships between drain current Id and gate voltage VG can form corresponding current-voltage curves. For example, FIG. 3 illustrates the first current-voltage curve Crv1 corresponding to the main array 116, the second current-voltage curve Crv2 corresponding to the test memory cell 114, and the third current-voltage curve Crv3 corresponding to the mini array 112, with the horizontal axis representing the gate voltage VG (unit: volt) and the vertical axis representing the drain current Id (unit: ampere). The first current-voltage curve Crv1 becomes flat when the drain current Id reaches about 1E-03 ampere. Since the drain current Id refers to the sum of the currents flowing from the source to the drain of each memory cell included, under the same gate voltage VG, the drain current Id of the first current-voltage curve Crv1 is greater than the drain current Id of the third current-voltage curve Crv3, and the drain current Id of the third current-voltage curve Crv3is greater than the drain current Id of the second current-voltage curve Crv2.

The memory control circuit 120 may record the formed first current-voltage curve Crv1, second current-voltage curve Crv2, and third current-voltage curve Crv3in its internal memory. In addition, although in the example of FIG. 3, the range of the gate voltage VG of the current-voltage curves is from 0 volt to 10 volts, the present invention is not limited to this. Basically, the range of the gate voltage VG of the current-voltage curves required in this embodiment mainly focuses on the linear region (for example: 0 volt to 4 volts), without considering the saturation region.

In step S204, the memory control circuit 120 analyzes the second current-voltage curve Crv2 corresponding to the test memory cell 114 and the third current-voltage curve Crv3 corresponding to the mini array 112, to obtain a target middle voltage point Vtmed. The implementation details of step S204 may reference the steps in FIG. 4. First, in step S400, the memory control circuit 120 performs differential on the third current-voltage curve Crv3 corresponding to the mini array 112, to identify a maximum value of the differential result as a first maximum value. Specifically, the memory control circuit 120 may perform differential (dId/dVG) on each point on the third current-voltage curve Crv3, and identify the maximum value from all differential results (physically equivalent to transconductance (gm)) as the first maximum value.

In step S402, the memory control circuit 120 serves the gate voltage VG corresponding to the first maximum value as an initial middle voltage point Vtmed_gmmax. Specifically, the memory control circuit 120 may serve the gate voltage VG of the point with the maximum differential result (transconductance) on the third current-voltage curve Crv3 as the initial middle voltage point Vtmed_gmmax.

In step S404, the memory control circuit 120 performs differential on the second current-voltage curve Crv2 corresponding to the test memory cell 114, to identify a maximum value of the differential result as a second maximum value. Specifically, the memory control circuit 120 may perform differential (dId/dVG) on each point on the second current-voltage curve Crv2, and identify the maximum value from all differential results as the second maximum value.

In step S406, the memory control circuit 120 serves the gate voltage VG corresponding to the second maximum value as a maximum value voltage Vmax. Specifically, the memory control circuit 120 may serve the gate voltage VG of the point with the maximum differential result (transconductance) on the second current-voltage curve Crv2 as the maximum value voltage Vmax.

In step S408, the memory control circuit 120 identifies the gate voltage VG when the drain current Id is at a low current value for the second current-voltage curve Crv2, and serves it as a low current gate voltage VG_low. Specifically, the memory control circuit 120 may serve the gate voltage VG of the point on the second current-voltage curve Crv2 where the drain current Id is at the low current value (for example, 1n ampere) as the low current gate voltage VG_low.

In step S410, the memory control circuit 120 subtracts the low current gate voltage VG_low from the maximum value voltage Vmax to calculate an offset value ΔV (ΔV=Vmax-VG_low).

In step S412, the memory control circuit 120 subtracts the offset value ΔV from the initial middle voltage point Vtmed_gmmax to calculate the target middle voltage point Vtmed (Vtmed=Vtmed_gmmax-ΔV). It should be noted that, since the mini array 112 is more intrinsic, after subtracting the offset value ΔV from the initial middle voltage point Vtmed_gmmax obtained according to the third current-voltage curve Crv3 corresponding to the mini array 112 (i.e., the target middle voltage point Vtmed), may serve it as the threshold voltage Vt where the peak of a threshold voltage distribution Dvt to be illustrated is located.

Referring back to FIG. 2, in step S206, the memory control circuit 120 analyzes the first current-voltage curve Crv1 corresponding to the main array 116 to obtain a left range length LRG. The implementation details of step S206 may reference each step in FIG. 5. First, in step S500, the memory control circuit 120 identifies the gate voltage VG when the drain current Id is at the low current value for the first current-voltage curve Crv1, and serves it as a left range voltage point VL. Specifically, since the range to the left of the peak of the threshold voltage distribution Dvt needs to consider the tailing bit and the tailing bit can only be detected when the drain current Id is at the low current value, the memory control circuit 120 may serve the gate voltage VG of the point on the first current-voltage curve Crv1 corresponding to the main array 116 with the largest size where the drain current Id is at the low current value (for example, 1n ampere) as the left range voltage point VL.

In step S502, the memory control circuit 120 subtracts the left range voltage point VL from the target middle voltage point Vtmed to calculate the left range length LRG. Specifically, the memory control circuit 120 may subtract the left range voltage point VL from the target middle voltage point Vtmed and take the absolute value, thus obtaining the left range length LRG (LRG=|Vtmed-VL|).

Referring back to FIG. 2, in step S208, the memory control circuit 120 analyzes the third current-voltage curve Crv3 corresponding to the mini array 112 to obtain a right range length RRG. The implementation details of step S208 may reference each step in FIG. 6. First, in step S600, the memory control circuit 120 identifies the gate voltage VG when the drain current Id is at the low current value for the third current-voltage curve Crv3, and serves it as a mini array right range voltage point VRm. Specifically, since the range to the right of the peak of the threshold voltage distribution Dvt will not have tailing bits, the memory control circuit 120 may serve the gate voltage VG of the point on the third current-voltage curve Crv3 corresponding to the more intrinsic mini array 112 where the drain current Id is at the low current value (for example, 1n ampere) as the mini array right range voltage point VRm.

In step S602, the memory control circuit 120 subtracts the mini array right range voltage point VRm from the target middle voltage point Vtmed to calculate a mini array right range length RRGm. Specifically, the memory control circuit 120 may subtract the mini array right range voltage point VRm from the target middle voltage point Vtmed and take the absolute value, thus obtaining the mini array right range length RRGm (RRGm=|Vtmed-VRm|).

Next, in step S604, since the threshold voltage distribution Dvt to be illustrated represents the threshold voltage distribution of the memory chip 110, which mainly needs to reflect the characteristics of the main array 116 (for example, 512k bits), the memory control circuit 120 multiplies the mini array right range length RRGm obtained from the third current-voltage curve Crv3 corresponding to the mini array 112 by a statistical ratio α in statistics to calculate the right range length RRG (RRG=αRRGm).

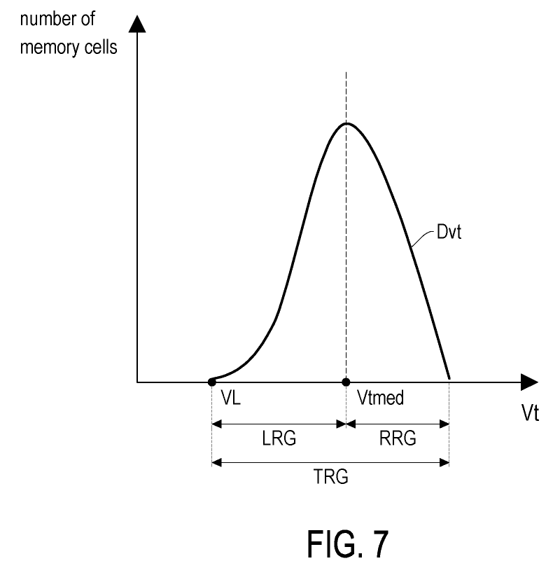

Finally, in step S210 of FIG. 2, the memory control circuit 120 draws the threshold voltage distribution Dvt according to the target middle voltage point Vtmed, the left range length LRG, and the right range length RRG. For example, FIG. 7 illustrates the threshold voltage distribution Dvt of the memory chip 110, with the horizontal axis representing the threshold voltage Vt and the vertical axis representing the number of memory cells. The memory control circuit 120 may use the target middle voltage point Vtmed as the threshold voltage Vt where the peak of the threshold voltage distribution Dvt is located, use the left range length LRG as the distance between the target middle voltage point Vtmed and the left distribution boundary (left range voltage point VL), use the right range length RRG as the distance between the target middle voltage point Vtmed and the right distribution boundary, and draw the threshold voltage distribution Dvt in a simulated Gaussian distribution mode.

Through the testing method described above, there is no need to test each memory cell (bit), and the threshold voltage distribution Dvt of the memory chip 110 can be quickly evaluated, which may effectively reduce the required test time. The drawn threshold voltage distribution Dvt may also take into account the tail bits portion. In addition, when using low current values for measurement, even for the main array 116 with the largest size, it will not be limited by the current limiting problem of the equipment.

In one implementation, the memory control circuit 120 may also compare the total range length TRG obtained by adding the left range length LRG and the right range length RRG with a predetermined reference range length, to confirm whether the total range length TRG of the drawn threshold voltage distribution Dvt has abnormal conditions of being too long or too short. According to the confirmation result, the memory control circuit 120 may determine whether the drawn threshold voltage distribution Dvt is normal, and decide whether it may serve as the formal test result.

In summary, the flash memory device and the testing method thereof of the present invention can evaluate the threshold voltage distribution of the chip with less test time and cost. As a result, it is beneficial for improving product development, yield verification, wafer probing and other procedures, enhancing the efficiency of chip calibration.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A flash memory device, comprising:
a memory chip, having a mini array, a test memory cell and a main array; and
a memory control circuit, coupled to the memory chip, configured to perform an erase operation on the mini array, the test memory cell and the main array, and then measures a relationship between a drain current and a gate voltage for each of the mini array, the test memory cell and the main array, to record a first current-voltage curve, a second current-voltage curve and a third current-voltage curve respectively corresponding to the main array, the test memory cell and the mini array,
wherein, the memory control circuit analyzes the second current-voltage curve and the third current-voltage curve to obtain a target middle voltage point, the memory control circuit analyzes the first current-voltage curve to obtain a left range length, the memory control circuit analyzes the third current-voltage curve to obtain a right range length,
the memory control circuit draws a threshold voltage distribution according to the target middle voltage point, the left range length and the right range length.

2. The flash memory device as claimed in claim 1, wherein the memory control circuit performs differential on the third current-voltage curve to identify a maximum value of a differential result as a first maximum value, and serves the gate voltage corresponding to the first maximum value as an initial middle voltage point,
the memory control circuit subtracts an offset value from the initial middle voltage point to calculate the target middle voltage point.

3. The flash memory device as claimed in claim 2, wherein the memory control circuit performs differential on the second current-voltage curve to identify a maximum value of a differential result as a second maximum value, and serves the gate voltage corresponding to the second maximum value as a maximum value voltage,
the memory control circuit identifies the gate voltage when the drain current is at a low current value for the second current-voltage curve, and serves it as a low current gate voltage,
the memory control circuit subtracts the low current gate voltage from the maximum value voltage to calculate the offset value.

4. The flash memory device as claimed in claim 1, wherein the memory control circuit identifies the gate voltage when the drain current is at a low current value for the first current-voltage curve, and serves it as a left range voltage point,
the memory control circuit subtracts the left range voltage point from the target middle voltage point to calculate the left range length.

5. The flash memory device as claimed in claim 1, wherein the memory control circuit identifies the gate voltage when the drain current is at a low current value for the third current-voltage curve, and serves it as a mini array right range voltage point,
the memory control circuit subtracts the mini array right range voltage point from the target middle voltage point to calculate a mini array right range length, and multiplies the mini array right range length by a statistical ratio to calculate the right range length.

6. The flash memory device as claimed in claim 1, wherein the memory control circuit compares a total range length obtained by adding the left range length and the right range length with a reference range length to determine whether the drawn threshold voltage distribution is normal.

7. A testing method of a flash memory device, wherein the flash memory device comprises a mini array, a test memory cell and a main array, the testing method comprising:
performing an erase operation on the mini array, the test memory cell and the main array;
measuring a relationship between a drain current and a gate voltage for each of the mini array, the test memory cell and the main array, to record a first current-voltage curve, a second current-voltage curve and a third current-voltage curve respectively corresponding to the main array, the test memory cell and the mini array;
analyzing the second current-voltage curve and the third current-voltage curve to obtain a target middle voltage point;
analyzing the first current-voltage curve to obtain a left range length;
analyzing the third current-voltage curve to obtain a right range length; and
drawing a threshold voltage distribution according to the target middle voltage point, the left range length and the right range length.

8. The testing method as claimed in claim 7, wherein the step of analyzing the second current-voltage curve and the third current-voltage curve to obtain the target middle voltage point comprises:
performing differential on the third current-voltage curve to identify a maximum value of a differential result as a first maximum value;
serving the gate voltage corresponding to the first maximum value as an initial middle voltage point; and
subtracting an offset value from the initial middle voltage point to calculate the target middle voltage point.

9. The testing method as claimed in claim 8, wherein the step of analyzing the second current-voltage curve and the third current-voltage curve to obtain the target middle voltage point further comprises:
performing differential on the second current-voltage curve to identify a maximum value of a differential result as a second maximum value;
serving the gate voltage corresponding to the second maximum value as a maximum value voltage;
identifying the gate voltage when the drain current is at a low current value for the second current-voltage curve, and serving it as a low current gate voltage; and
subtracting the low current gate voltage from the maximum value voltage to calculate the offset value.

10. The testing method as claimed in claim 7, wherein the step of analyzing the first current-voltage curve to obtain the left range length comprises:
identifying the gate voltage when the drain current is at a low current value for the first current-voltage curve, and serving it as a left range voltage point; and
subtracting the left range voltage point from the target middle voltage point to calculate the left range length.

11. The testing method as claimed in claim 7, wherein the step of analyzing the third current-voltage curve to obtain the right range length comprises:
identifying the gate voltage when the drain current is at a low current value for the third current-voltage curve, and serving it as a mini array right range voltage point;
subtracting the mini array right range voltage point from the target middle voltage point to calculate a mini array right range length; and
multiplying the mini array right range length by a statistical ratio to calculate the right range length.

12. The testing method as claimed in claim 7, further comprising:
comparing a total range length obtained by adding the left range length and the right range length with a reference range length to determine whether the drawn threshold voltage distribution is normal.
